(19) United States
(12) Patent Application Publication
(10) Pub. No.: US 2007/0140023 A1
(43) Pub. Date: Jun. 21, 2007

(54) Integrated dynamic random access memory chip

(76) Inventors: Wolfgang Helfer, Dresden (DE); Arndt Gruber, Munchen (DE)

Correspondence Address: PATTERSON & SHERIDAN, LLP;Gero McClellan / Infineon / Qimonda, 3040 POST OAK BLVD.,, SUITE 1500, HOUSTON, TX, 77056, US

(21) Appl. No.: 11/304,060

(22) Filed: Dec. 15, 2005

(51) Int. Cl. G11C 29/00; G11C 7/00

(52) U.S. Cl. 365/200

(57) ABSTRACT

An integrated dynamic random access memory chip is provided, the memory chip comprising a plurality of volatile memory cells for storing user data and a plurality of non-volatile rewritable memory cells for storing at least one of repair data, trimming data, sorting data and identification data.

### BACKGROUND OF THE INVENTION

1. Field of the Invention

The present invention is related to an integrated dynamic random access memory (DRAM) chip having additional memory cells for storing data other than user data.

2. Description of the Related Art

In today's DRAM memory devices, usually non-volatile ROM (i.e., read only memory) memory cells are provided to permanently store specific data such as repair data, trimming data, sorting data and identification data. Conventionally, these memory cells provided as so-called laser fuses or electrical fuses (E-fuses). Laser fuses are conducting elements which can be cut by means of an external laser pulse, and electrical fuses are provided as a dielectric material sandwiched between two electrodes wherein the electrical fuses are initially non-conducting and which can be made conducting by applying a high electrical field such that a breakdown voltage is exceeded. Thereby, a conducting path is formed within the dielectric material. Since the number of ROM memory cells is typically between 10,000 and 20,000, for example, for a 512 MB DRAM device, the size of each single ROM memory cell may be critical as the overall size of the ROM memory unit may occupy a substantial portion of the overall active chip area. Consequently, the size of each single ROM memory cell has a relevant impact from the required chip area for the DRAM device.

Laser fuses and electrical fuses have a further disadvantage that they can only be programmed once, wherein after the laser fuse has been molten or the electrical fuse has been made conductive, a further modification of the respective fuse element is not possible. Thus, there is no further modification of the data stored in the fuse element, e.g., data which is generated after supplying the DRAM device to the customer or after the DRAM device has been implemented in a final application. Such data may include a total operation time of the chip, the operation temperature and operation frequency profiles over the lifetime of the device, maximum of the temperature, as well as memory addresses of DRAM memory cells in which an error occurs sporadically. Such data may be helpful while analyzing the errors of DRAM memory chip which already have been implemented in final applications at the customer and returned to the manufacturer as a “customer returned device”.

Furthermore, a DRAM memory comprises a number of redundant memory cells which can be made addressable if one or more regular dynamic memory cells of the DRAM memory are defective. The defective memory cells are determined by a front-end test procedure and for a back-end test procedure such that repair data is generated, and laser fuses or electrical fuses are programmed depending on the repair data such that the redundant memory cells are virtually replaced by the regular dynamic memory cells to correct the error. If any further regular dynamic memory cell showed a defect during the normal operation of the DRAM memory device, a further repair of memory cells would be necessary. Such a further repair may be impossible if no further unused fuse elements are available to replace regular dynamic memory cells with redundant memory cells.

Therefore, there is a need to provide an integrated DRAM memory chip having a capability to provide data, other than user data which is generated during the operation of the DRAM memory device, in the final application such that the DRAM memory device may be analyzed at the manufacturer's side when returned from the customer.

There is also a need to provide an integrated dynamic random access memory chip in which a repair of defective dynamic memory cells may be carried out after the memory chip has been packaged and shipped and has already been operated in a final application.

There is a further need to provide a method for repairing an integrated dynamic random access memory chip after the memory chip has been packaged and shipped and already operated in a final application.

### SUMMARY OF THE INVENTION

According to a first aspect of the present invention, an integrated dynamic random access memory chip is provided comprising a plurality of dynamic memory cells for storing user data and a number of non-volatile rewritable memory cells for storing at least one of repair data, trimming data, sorting data and identification data.

The provision of the non-volatile rewritable memory cells allows for storage of additional data other than user data in the dynamic random access memory chip which are generated during the normal operation of the memory chip, after packaging and shipping out of the memory chip to the customer. In this context, repair data is data which is generated depending on defects of the dynamic memory cells indicating, e.g., one or more addresses of the dynamic memory cells which are defect. Trimming data in this context means data used for settings which influence the operation of the memory chip, such as calibration data for calibrating a voltage or current supply source and the like. Sorting data is data used for classification of the memory chip with respect to the performance of the memory chip such that a chip, the performance of which has deteriorated over time, maybe assigned to another classification, for example, and the sorting data may be rewritten after such time. Identification data in this context means the identification number or string for characterizing the type of memory chip as well as to assign a unique chip ID.

The provision of non-volatile rewritable memory cells allows for changing of internal settings of the memory chip after finishing the manufacturing of the chip and its shipping out when the customer has returned the memory chip due to a defect or an improper behavior. The respective returned memory chip need not be discarded since the returned memory chips can be repaired, reclassified and/or retrimmed for a same or a new final application.

According to one embodiment, the plurality of non-volatile rewritable memory cells is formed as flash memory cells. Since flash memory cells can be integrated having a low area requirement, the portion of the chip area required by the non-volatile rewritable memory cells can be reduced or restricted.

According to another aspect of the present invention, an integrated dynamic random access memory chip is provided comprising a plurality of regular dynamic memory cells, a plurality of redundant memory cells and a plurality of non-volatile rewritable memory cells for storing repair data. Furthermore, an address unit is provided for addressing one or more regular dynamic memory cells for writing to and reading out user data depending on a provided address data. A redundancy unit is designed so that, depending on the repair data which is stored in the plurality of non-volatile rewritable memory cells, either one or more regular dynamic memory cells or one or more redundant memory cells are addressed by the address unit. Thus, by storing repair data in the non-volatile rewritable memory cells, defective regular dynamic memory cells can be repaired by virtually replacing them by redundant memory cells while addressing.

Preferably, the plurality of non-volatile rewritable memory cells is formed as flash memory cells.

Furthermore, a monitoring unit may be included for monitoring the operating of the memory chip and for generating further repair data if an error occurs. The redundancy unit may be further adapted to combine the repair data already stored and the further repair data to combined repair data and to rewrite the combined repair data into the plurality of non-volatile rewritable memory cells. Thereby, the further repair data can be added to the repair data already stored and can be combined in such a way that a new repair scheme can be determined to completely replace the regular memory cells with redundant memory cells such that the memory chip can be used and need not be discarded.

According to a further aspect of the present invention, an integrated dynamic random access memory chip is provided comprising a plurality of regular dynamic memory cells, a plurality of non-volatile rewritable memory cells for storing setting data, a control unit for controlling a timing of the accesses of the dynamic memory cells during a write or a read operation, and a setting unit for setting the timing for addressing one or more regular memory cells depending on the setting data.

Thereby, the timing parameters which change within the memory chip during a lifetime can be addressed by changing the setting data such that the memory chip can remain within the specification.

According to a further aspect of the present invention, an integrated dynamic access memory chip is provided comprising a plurality of regular dynamic memory cells, a plurality of non-volatile rewritable memory cells for storing setting data, a settable voltage source for providing a predetermined internal potential within the integrated memory chip and a setting unit for reading out the setting data from the plurality of non-volatile rewritable memory cells and for setting the voltage source depending on the readout setting data.

Thereby, a degradation of the circuit elements of the memory chip concerning the voltage source can be addressed if the degradation results in a change of the voltage output by the voltage source such that the voltage can be recalibrated in a memory chip when a voltage source has been degraded due to aging.

According to another aspect of the present invention, a method for repairing an integrated dynamic random access memory chip is provided, the integrated DRAM chip comprising a plurality of regular dynamic memory cells, a plurality of redundant memory cells and a plurality of non-volatile rewritable memory cells for storing repair data. The method comprises performing a first test on at least the plurality of regular dynamic memory cells, wherein first repair data are generated indicating which of the regular memory cells are defective, weighing the first repair data to the plurality of non-volatile rewritable memory cells such that, depending on the first repair data, either one or more regular dynamic memory cells or one or more redundant memory cells are addressed. After a period of time, a second test is performed on at least one of the plurality of regular dynamic memory cells, wherein second repair data are generated indicating which of the regular memory cells are defective. The first and second repair data are combined to obtain combined repair data. The combined repair data are rewritten into the plurality of non-volatile rewritable memory cells such that, depending on the combined repair data, either one or more regular dynamic memory cells or one or more redundant memory cells are addressed.

In one embodiment, between the first and the second test, packaging of the memory chip has been performed, and the memory chip has been shipped to the customer the memory chip is implemented in a final application where the memory chip is subjected to normal applications until an error occurs.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is block diagram of a dynamic random access memory chip according to an embodiment of the present invention;

FIG. 2 a block diagram of a memory chip according to another embodiment of the present invention; and

FIG. 3 a block diagram of a memory chip according to another embodiment of the present invention.

### DETAILED DESCRIPTION OF THE PREFERRED EMBODIMENT

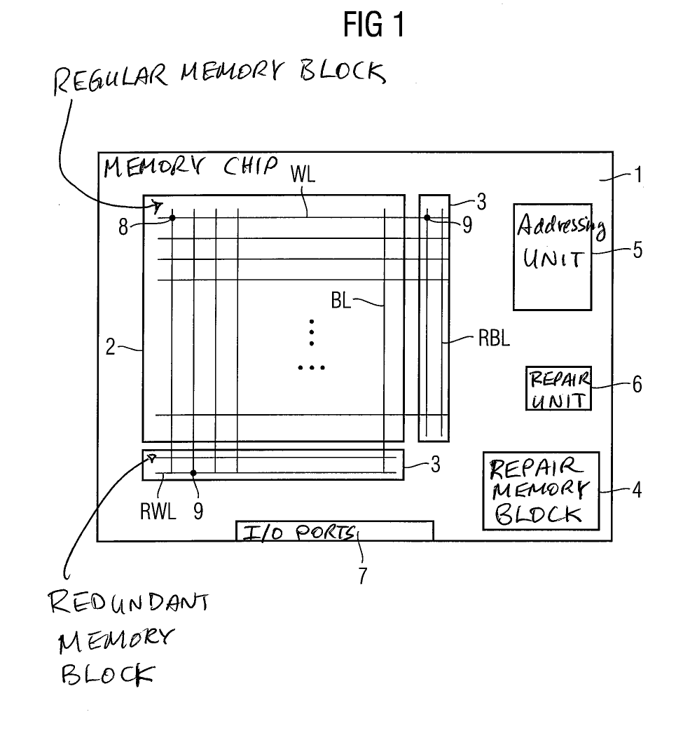

In FIG. 1, a block diagram of a dynamic random access memory chip 1 is shown. The memory chip 1 comprises a memory cell array 2 including regular memory cells 8 and a redundant cell array 3 including redundant memory cells 9. The redundant memory cells 9 in the redundant cell array 3 are usually arranged close to or adjacent the regular memory array 2 such that a plurality of redundant memory cells are arranged on the word lines WL of the regular memory array and redundant bit lines RBL and a further plurality of redundant memory cells are arranged on the bit lines BL of the regular memory array 2 and redundant word lines RWL. Furthermore, a repair memory block 4 is provided including non-volatile rewritable memory cells for storing repair data. The repair memory block 4 preferably include flash memory cells or any other kind of non-volatile memory cells which can be rewritten, such as resistive memory cells, e.g., programmable metallization cell (PMC) memory cells, phase change memory cells and the like.

The repair data indicates which of the word lines including the dynamic memory cells arranged thereon and/or which of the bit lines and the memory cells arranged thereon are to be replaced by a redundant word line RWL or a redundant bit line RBL such that the memory cells along the regular word line/bit line WL/BL are replaced by the memory cells of the redundant word line/bit line RWL/URBL. This means that if one memory cell out of the plurality of memory cells of a word line or of a bit line is defective, all of the memory cells of the word line or bit line have to be replaced by the respective redundant memory cells on the redundant word line RWL or redundant bit line RBL. The replacement is done by the addressing unit 5 which addresses the memory cells depending on addresses provided externally and on the repair data stored in the repair memory block 4. The addressing unit 5 may comprise a redundancy unit which is responsible for the rerouting of the applied addresses such that redundant memory cells 9 are addressed instead of regular memory cells 8.

The repair data stored in the repair memory block 4 allows control of the replacement of the regular memory cells with the redundant memory cells. The repair data stored in the repair memory block 4 is generated after performing a plurality of test procedures wherein a first test procedure is usually carried out while the memory chips are arranged on the wafer and are not separated. According to the repair data which depend on detected defect memory cells in the regular memory block 2, the non-volatile rewritable memory cells in the repair memory block 4 are written with the repair data such that, while addressing the memory cells of the memory chip 1, either regular or redundant memory cells of the regular and redundant memory blocks 2, 3 are addressed depending on the repair data.

While embedding the integrated memory circuit into a package and/or when implementing the memory chip package in a module, additional stress is applied onto the memory cell such that additional defects in regular memory cells can occur. By performing an additional test, the additional defects can be uncovered, and the repair data have to be modified to replace each of the defective regular memory cells with redundant memory cells. In conventional memory chips, this is possible only in case that after the previous repair cycle unused redundant memory cells (redundant word lines RWL/redundant bit lines RBL) are available. When using the non-volatile rewritable memory cells, it is possible to generate additional repair data and to overwrite the repair data already stored in the repair memory block with the newly generated repair data.

The additional repair data can be generated by a repair unit 6 internally which reads out the repair data stored in the repair memory block 4 and by combining the read out repair data and the newly detected repair data. The additional repair data is then rewritten in the repair memory block 4. Thereby, it may be possible to repair defect memory cells of the memory chip 1 even after the memory chip has been operated within a final application. The further repair data can be internally generated in a test unit or can be externally provided via respective I/O ports 7 of the memory chip 1.

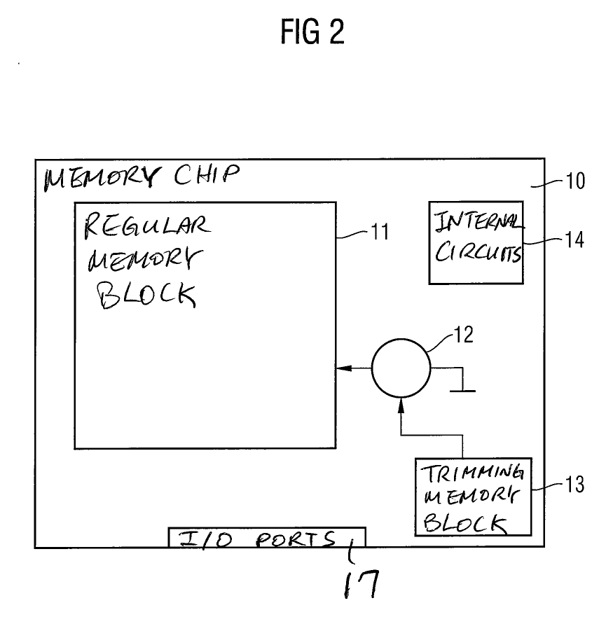

In FIG. 2, a block diagram of a memory chip 10 according to another embodiment of the present invention is illustrated. The memory chip 10 includes a regular memory block 11 and a plurality of voltage sources 12 which generate predetermined voltages using external voltages applied via I/O ports 17 of the memory chip 10. For example, such predetermined voltages can be potentials which are higher or lower than the potentials applied with the external voltages at the respective I/O ports. Due to process tolerances during the manufacturing of the memory chip, the voltages generated by the voltage sources are subjected to tolerances especially when the chip has been manufactured using typical DRAM technology. The voltage source 12 can be calibrated by means of setting data stored in a trimming memory block 13. The trimming memory block 13 includes non-volatile rewritable memory cells which may be formed by flash memory cells and the like as described above. Conventional fuse elements which are normally used for such a trimming of a calibratable voltage source 12 cannot be reprogrammed after the device has been packaged, and thus, the voltage source cannot be readjusted. Furthermore, after performing the test procedure on the memory chip, the electrical behavior of the components of the memory chip may change, and a re-adjustment of the trimming of the voltage source 12 may be needed. By providing the trimming memory block 13 comprising the non-volatile rewritable memory cells, such a re-adjustment can be carried out by simply overwriting the non-volatile rewritable memory cells with a new trimming data determined by the test procedure. In the trimming memory block 13, a trimming value is stored which can be increased or decreased resulting in that the voltage source 12 increases or decreases the output voltage applied to the internal circuits 14 of the memory chip 10.

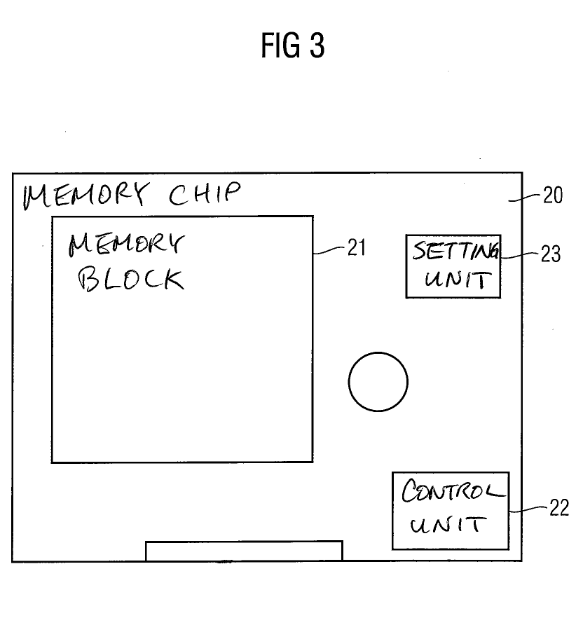

In FIG. 3, a DRAM memory chip 20 according to another embodiment of the present invention is shown. The DRAM memory chip 20 comprises a memory block 21 and a control unit 22 for controlling access times to the memory block 21 during a write operation or a read operation. In a setting unit 23, the access times can be set such that the addressing of the memory block (memory cells therein) is carried out depending on the setting stored in the setting unit 23. The setting unit 23 includes non-volatile rewritable memory cells for storing the setting data.

For each embodiment described above, additional data such as sorting data, classification data and identification data can be stored in the non-volatile rewritable memory cells. Furthermore, the features of the described embodiments can be integrated together in a DRAM memory device.

While the foregoing is directed to embodiments of the present invention, other and further embodiments of the invention may be devised without departing from the basic scope thereof, and the scope thereof is determined by the claims that follow.

1. An integrated dynamic random access memory chip, comprising:
a plurality of volatile memory cells for storing user data and for being written to and read from during normal operation of the chip;
a plurality of non-volatile rewritable memory cells for storing at least one of repair data, trimming data, sorting data, and identification data.

2. The memory chip of claim 1, wherein the non-volatile rewritable memory cells comprise flash memory cells.

3. An integrated dynamic random access memory chip, comprising:
a plurality of regular volatile memory cells;
a plurality of redundant volatile memory cells;
a plurality of non-volatile rewritable memory cells for storing repair data;
an address unit for addressing one or more regular dynamic memory cells for writing to and reading out normal data depending on a provided address data; and
a redundancy unit configured to control addressing of the address unit, wherein, depending on the repair data which is stored in the plurality of non-volatile rewritable memory cells, the address unit selectively addresses one of:
one or more regular volatile memory cells; and
one or more redundant volatile memory cells.

4. The memory chip of claim 3, wherein the non-volatile rewritable memory cells comprise flash memory cells.

5. The memory chip of claim 4, further comprising:
a monitoring unit for monitoring operation of the memory chip and for generating further repair data when an error occurs; and
wherein the redundancy unit is further configured to combine the repair data already stored and the further repair data to form a combined repair data and to rewrite the combined repair data into the plurality of non-volatile rewritable memory cells.

6. An integrated dynamic random access memory chip, comprising:
a plurality of regular volatile memory cells;
a plurality of non-volatile rewritable memory cells for storing setting data;
a control unit for controlling access timing to the dynamic memory cells during a write operation or a read operation; and
a setting unit for setting the access timing for addressing one or more regular memory cells depending on the setting data.

7. The memory chip of claim 6, wherein the non-volatile rewritable memory cells comprise flash memory cells.

8. An integrated dynamic random access memory chip, comprising:
a plurality of regular volatile memory cells;
a plurality of non-volatile rewritable memory cells for storing setting data;
a settable voltage source for providing a predetermined internal potential within the memory chip;
a setting unit for reading out the setting data from the plurality of non-volatile rewritable memory cells and for setting the voltage source depending on the read out setting data.

9. The memory chip of claim 8, wherein the non-volatile rewritable memory cells comprise flash memory cells.

10. A method for repairing an integrated dynamic random access memory chip, comprising:
performing a first test on at least a plurality of regular volatile memory cells, wherein first repair data are generated indicating which of the regular memory cells are defective;
writing the first repair data to a plurality of non-volatile rewritable memory cells on the memory chip, wherein depending on the first repair data, either one or more regular dynamic memory cells or one or more redundant memory cells are addressed;
performing a second test on at least one of the plurality of regular volatile memory cells, whereby second repair data are generated indicating which of the regular memory cells are defective;
combining the first and the second repair data to obtain combined repair data; and
rewriting the combined repair data into the plurality of non-volatile rewritable memory cells, wherein depending on the combined repair data, either one or more regular volatile memory cells or one or more redundant memory cells are addressed.

11. The method of claim 10, further comprising:
performing a plurality of process steps utilizing the memory chip between performances of the first test and the second test.

12. The method of claim 11, wherein a packaging process of the memory chip is performed between performances of the first and the second test.

13. The method of claim 10, wherein, between performances of the first and the second test, the memory chip is subjected to a normal application until one or more errors have occurred.

14. An integrated dynamic random access memory chip, comprising:
a memory cell array comprising a plurality of volatile memory cells arranged in a matrix of word lines and bit lines; and
a plurality of non-volatile rewritable memory cells for storing updatable adjustment data for adjusting operations of the memory chip.

15. The memory chip of claim 14, further comprising:
a redundant memory array comprising a plurality of volatile memory cells;
wherein the adjustment data comprises addresses of defective memory cells in the memory cell array and replacement addresses of memory cells in the redundant cell array.

16. The memory chip of claim 15, further comprising:
a repair unit for generating additional repair data during normal operation of the memory chip and updating the adjustment data stored in the plurality of non-volatile rewritable memory cells.

17. The memory chip of claim 14, further comprising:
a plurality of voltage sources for providing voltages in the memory chip;
wherein the adjustment data comprises one or more trimming values for setting the respective voltages provided by the plurality of voltage sources.

18. The memory chip of claim 14, further comprising:
a control unit for controlling access times to the volatile memory cells;
wherein the adjustment data comprises setting data for access times to the volatile memory cells in a read operation and in a write operation.

19. The memory chip of claim 14, further comprising:
a repair unit configured to
generate additional repair data based on results of the additional tests; and
updating the adjustment data stored in the plurality of non-volatile rewritable memory cells with the additional repair data.

20. The memory chip of claim 14, wherein the repair unit is further configured to perform one or more additional tests on the memory chip after the memory chip has been packaged and utilized in normal operations.
